(19) United States
(12) Patent Application Publication
(10) Pub. No.: US 2014/0131068 A1
(43) Pub. Date: May 15, 2014

(54) CIRCUIT BOARD AND METHOD FOR MANUFACTURING THE SAME

(71) Applicant: Samsung Electro-Mechanics Co., Ltd., Suwon (KR)

(72) Inventor: Byeong Mun Kim, Busan (KR)

(73) Assignee: Samsung Electro-Mechanics Co., Ltd., Suwon (KR)

(21) Appl. No.: 14/051,051

(22) Filed: Oct. 10, 2013

(30) Foreign Application Priority Data
Nov. 12, 2012 (KR) 10-2012-0127485

(51) Int. Cl. H05K 1/02; H05K 3/46

(52) U.S. Cl. CPC H05K 1/0298; H05K 3/46
USPC 174/251; 216/20

(57) ABSTRACT

Disclosed herein is a circuit board including: a core layer; first and second layers sequentially stacked on the core layer, wherein prominence-depressions having different sizes are formed on a surface of the first layer in each region of the core layer.

### CROSS REFERENCE(S) TO RELATED APPLICATIONS

This application claims the benefit under 35 U.S.C. Section 119 of Korean Patent Application Serial No. 10-2012-0127485, entitled “Circuit Board and Method for Manufacturing the Same” filed on Nov. 12, 2012, which is hereby incorporated by reference in its entirety into this application.

### BACKGROUND OF THE INVENTION

1. Technical Field

The present invention relates to a circuit board and a method for manufacturing the same, and more particularly, to a circuit board in which reliability of bonding between layers is improved, and a method for manufacturing the same.

2. Description of the Related Art

Recently, in accordance with slimness of electronic products and improvement in performance of the electronic products, thinness and multi-layering of various circuit boards such as a printed circuit board (PCB) have also been conducted. In order to satisfy both of the thinness and the multi-layering of the circuit board, circuit patterns having high density should be implemented. To this end, a technology for improving close adhesion or bonding force between an insulating layer and the circuit patterns or a metal layer used for other purposes has been demanded.

### RELATED ART DOCUMENT

### Patent Document

(Patent Document 1) Korean Patent Laid-Open Publication No. 10-2001-0021557

### SUMMARY OF THE INVENTION

An object of the present invention is to provide a circuit board in which reliability of bonding between layers is improved.

Another object of the present invention is to provide a circuit board in which close adhesion or bonding force between an insulating layer and a metal layer is improved.

Still another object of the present invention is to provide a method for manufacturing a circuit board in which reliability of bonding between layers is improved.

Yet still another object of the present invention is to provide a method for manufacturing a circuit board having a structure in which close adhesion or bonding force between an insulating layer and a metal layer is improved.

According to an exemplary embodiment of the present invention, there is provided a circuit board including: a core layer; a first layer covering the core layer; and a second layer covering the first layer, wherein prominence-depressions having different sizes are formed on a surface of the first layer in each region of the core layer.

The prominence-depressions may include: a first prominence-depression having a size equal to or larger than 15 μm, and a second prominence-depression having a size less than 15 μm.

The first layer may include a circuit pattern and a non-circuit pattern, prominence-depressions having different sizes may be formed on a surface of the non-circuit pattern, and a prominence-depression having a relatively small size among the prominence-depressions may be formed on a surface of the circuit pattern.

The first layer may include a circuit pattern and a non-circuit pattern, a first prominence-depression having a size equal to or larger than 15 μm and a second prominence-depression having a size less than 15 μm may be formed on a surface of the non-circuit pattern, and the second prominence-depression may be formed on a surface of the circuit pattern.

According to an exemplary embodiment of the present invention, there is provided a method for manufacturing a circuit board, including: preparing a base substrate having a core layer and a metal layer covering the core layer; forming a first layer having a circuit pattern and a non-circuit pattern by performing an etching process at different etching rates on the metal layer for each region; performing a roughing treatment process on the circuit pattern and the non-circuit pattern; and forming a second layer on the first layer.

The forming of the first layer may include forming a first prominence-depression on a surface of the non-circuit pattern, the first prominence-depression having a relatively large size, and the performing of the roughing treatment process may include forming a second prominence-depression on the circuit pattern and the non-circuit pattern, the second prominence-depression having a size smaller than that of the first prominence-depression.

The forming of the first layer may include forming a first prominence-depression on a surface of the non-circuit pattern, the first prominence-depression having a size equal to or larger than 15 μm, and the performing of the roughing treatment process may include forming a second prominence-depression on the circuit pattern and the non-circuit pattern, the second prominence-depression having a size less than 15 μm.

### BRIEF DESCRIPTION OF THE DRAWINGS

FIG. 1 is a view showing a circuit board according to an exemplary embodiment of the present invention;

FIG. 2 is an enlarged view of the region A shown in FIG. 1;

FIG. 3 is a graph showing a surface area change according to a change in a radius of a hemisphere;

FIG. 4 is a flow chart showing a method for manufacturing a circuit board according to the exemplary embodiment of the present invention; and

FIGS. 5 to 8 are views for describing a process for manufacturing a circuit board according to the exemplary embodiment of the present invention.

### DESCRIPTION OF THE PREFERRED EMBODIMENTS

Various advantages and features of the present invention and methods accomplishing thereof will become apparent from the following description of exemplary embodiments with reference to the accompanying drawings. However, the present invention may be modified in many different forms and it should not be limited to exemplary embodiments set forth herein. These exemplary embodiments may be provided so that this disclosure will be thorough and complete, and will fully convey the scope of the invention to those skilled in the art. Like reference numerals throughout the description denote like elements.

Terms used in the present specification are for explaining exemplary embodiments rather than limiting the present invention. Unless explicitly described to the contrary, a singular form includes a plural form in the present specification. The word “comprise” and variations such as “comprises” or “comprising,” will be understood to imply the inclusion of stated constituents, steps, operations and/or elements but not the exclusion of any other constituents, steps, operations and/or elements.

Hereinafter, a circuit board and a method for manufacturing the same according to exemplary embodiments of the present invention will be described in detail with reference to the accompanying drawings.

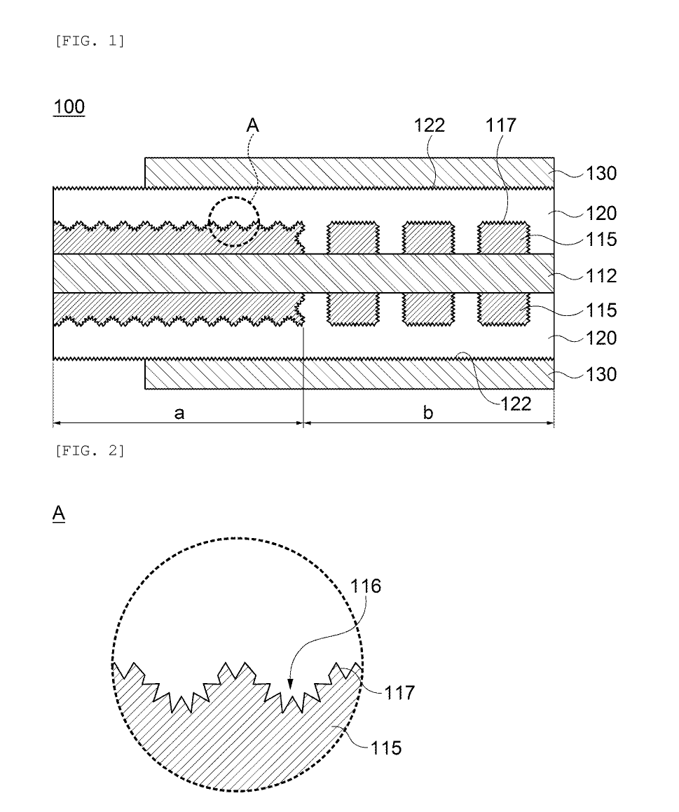

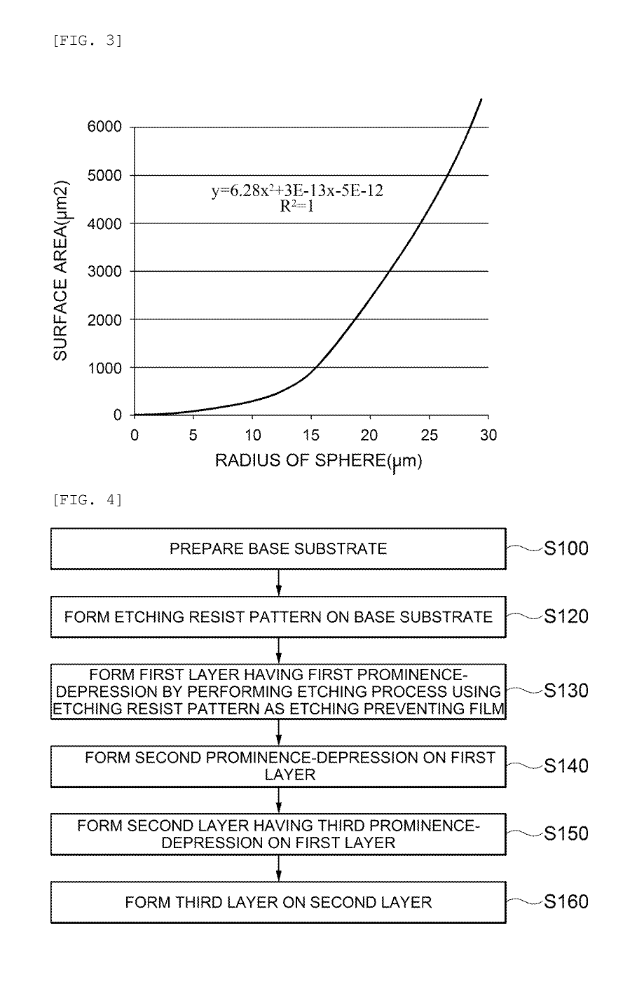

FIG. 1 is a view showing a circuit board according to an exemplary embodiment of the present invention; and FIG. 2 is an enlarged view of the region A shown in FIG. 1. In addition, FIG. 3 is a graph showing a surface area change according to a change in a radius of a hemisphere.

Referring to FIGS. 1 and 2, the circuit board 100 according to the exemplary embodiment of the present invention may be configured to include a core layer 112 and first to third layers 115, 120, and 130 sequentially stacked on the core layer 112.

The core layer 112 may be a base for manufacturing components of the circuit board 100. The core layer 112 may be positioned at the center of an inner portion of the circuit board 100, and the first to third layers 115, 120, and 130 may have a structure in which they are sequentially stacked on both surfaces of the core layer 112. Meanwhile, the core layer 112 may be divided into a first region a and a second region b other than the first region a.

The first layer 115 may cover both surfaces of the core layer 112. The first layer 115 may be a result obtained by patterning a predetermined metal layer. As an example, the first layer 115 may be a copper pattern. A portion positioned in the first region a in the first layer 115 may be a non-circuit pattern of the circuit board 100, and a portion positioned in the second region b in the first layer 115 may be a circuit pattern of the circuit board 100.

The second layer 120 may cover the first layer 115 and the core layer 112 exposed by the first layer 115, and the third layer 130 may cover the second layer 120. The second layer 120 may be an interlayer dielectric for electrical insulation between the first and second layers 115 and 130, and the third layer 130 may be a metal pattern formed on the second layer 120.

The first layer 115 may have a prominence-depression formed on a surface thereof. The prominence-depression, which is to increase a surface area of the first layer 115, may be formed by performing predetermined roughing treatment on the first layer 115. As an example, the prominence-depression may be configured of a first prominence-depression 116 and a second prominence-depression having a size relatively smaller than that of the first prominence-depression 116. The first prominence-depression 116 may be a depression part depressed from a surface of the first layer 115 up to a predetermined depth and generally having a hemispherical shape. On the other hand, the second prominence-depression 117 may have a size relatively smaller than that of the first prominence-depression 116 and be provided in a rough surface form over the entire surface of the first layer 115. That is, the first prominence-depression 116 may be provided in a bent form on the surface of the first layer 115; however, the second prominence-depression 117 may be formed in a rough surface form on the first layer 115.

The first prominence-depression 116 may have a size of about 15 μm or more. The size of the first prominence-depression 116 may be defined as a depth of the first prominence-depression 116 depressed from the surface of the metal layer 114, a width of the second prominence-depression 117, or the like. As shown in FIG. 3, since a surface area of a sphere is in proportion to a square of a radius of the sphere according to a formula: 4π r2, a surface area of the first prominence-depression 116 may be increased in proportion to an increase in the size of the first prominence-depression 116. In consideration of this, it is difficult to expect an effect of increasing the surface area of the first layer 115 in the case in which the first prominence-depression 116 has a size less than a predetermined size; however, it is possible to expect an effect of increasing the surface area of the first layer 115 in the case in which the first prominence-depression 116 has a size equal to or larger than the predetermined size. Therefore, as shown in FIG. 3, the first prominence-depression 116 has a size of 15 μm or more, more preferably, 20 μm or more, such that the surface of the first prominence-depression 116 may be increased. On the other hand, the second prominence-depression 117, which is provided in order to assist interlayer bonding force of the first prominence-depression 116, may have a size less than about 15 μm.

In addition, the first layer 115 may have the first and second prominence-depressions 116 and 117 selectively formed in each of the first and second regions a and b. For example, since the first layer 115 in the first region a is used as a non-circuit pattern, even though both of the first and second prominence-depressions 116 and 117 are formed on the first layer 115 in the first region a as shown in FIG. 2, a problem may not be generated in a function of the first layer 115 as the non-circuit pattern. However, since the first layer 115 in the second region b is used as a circuit pattern, in the case in which the first prominence-depression having a large size is provided in the first layer 115 in the second region b, characteristics of the first layer 115 as the circuit pattern may be deteriorated. Therefore, both of the first and second prominence-depressions 116 and 117 are formed at a portion of the first layer 115 as the non-circuit pattern and only the second prominence-depression 117 is selectively formed at a portion of the first layer 115 used as the circuit pattern, thereby making it possible to prevent deterioration of electrical characteristics of the circuit pattern and improve reliability of bonding between the first to third layers 115, 120, and 130.

As described above, the circuit board 100 according to the exemplary embodiment of the present invention includes the first and second layers 115 and 120 sequentially stacked on the core layer 112, and the first and second prominence-depressions 116 and 117 having different sizes are formed on the first layer 115, thereby making it possible to increase a bonding area between the first and second layers 115 and 120. Particularly, the first prominence-depression 116 is provided in a form in which it is depressed from the surface of the first layer 115 up to a depth of about 15 μm, thereby making it possible to significantly increase the surface area of the first layer 115. Therefore, the circuit board according to the exemplary embodiment of the present invention may have a structure in which the stacked first and second layers are provided and the prominence-depressions having different sizes are provided on the surface of the first layer to improve reliability of bonding between the first and second layers.

In addition, the circuit board 100 according to the exemplary embodiment of the present invention may include the first layer 115 formed on the core layer 112 and having the first and second prominence-depressions 116 and 117 formed on the surface thereof and the second layer 120 stacked on the first layer 115, wherein the first layer 115 may include the non-circuit pattern in which the first and second prominence-depressions 116 and 117 are formed and the circuit pattern in which only the second prominence-depression 117 is formed. Therefore, the circuit board according to the exemplary embodiment of the present invention may have a structure in which the prominence-depressions having different sizes are formed on the surface of the first layer in order to increase the bonding force between the first and second layers sequentially stacked on the core layer, only the prominence-depression having a relatively small size is provided in the portion used as the circuit pattern, and both of the prominence-depression having a relatively large size and the prominence-depression having a relatively small size are provided in the portion used as the non-circuit pattern to prevent deterioration of electrical characteristics of the circuit pattern and improve reliability of bonding between the layers.

Next, a method for manufacturing a circuit board according to the exemplary embodiment of the present invention will be described in detail. Hereinafter, a description of portions overlapped with those of the circuit board 100 according to the exemplary embodiment of the present invention described above will be omitted or simplified.

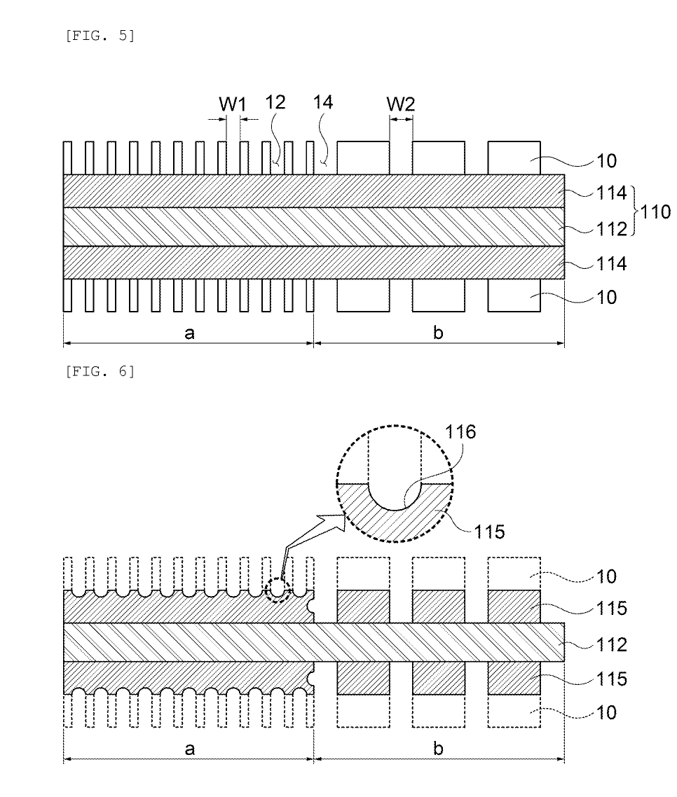

FIG. 4 is a flow chart showing a method for manufacturing a circuit board according to the exemplary embodiment of the present invention; and FIGS. 5 to 8 are views for describing a process for manufacturing a circuit board according to the exemplary embodiment of the present invention.

Referring to FIGS. 4 and 5, a base substrate 110 may be prepared (S110). As the base substrate 110, a thin plate including the core layer 112 and the metal layer 114 covering one surface or both surfaces of the core layer 112 may be used. As an example, a copper clad laminate (CCL) may be used as the base substrate 110. Meanwhile, the base substrate 110 may be divided into a first region a and a second region b other than the first region a. The first region a may be a region in which the non-circuit pattern of the circuit board 100 is provided, and the second region b may be a region in which the circuit pattern of the circuit board 100 is provided.

An etching resist pattern 10 may be formed on the base substrate 110 (S120). The forming of the etching resist pattern 10 may include forming a resist film on the base substrate 110 and patterning the resist film. The patterning of the resist film may include forming first openings 12 having a first width W1 in the resist film in the first region a and forming second openings 14 having a second width W2 in the resist film in the second region b. In a wet etching process using the etching resist pattern 10 as an etching resist film, which is the subsequent process, a size of the first opening 12 may be adjusted so that a portion of the metal layer 114 exposed by the first opening 12 is removed only up to a predetermined depth by an etchant, and a size of the second opening 14 may be adjusted so that a portion of the metal layer 114 exposed by the second opening 14 is removed to expose the core layer 112. To this end, the second width W1 may be larger than the first width W1.

Referring to FIGS. 4 to 6, the first layer 115 having the first prominence-depression 116 may be formed by performing the etching process using the etching resist pattern 10 as the etching resist film (S130). In the performing of the etching process, a wet etching process using a predetermined etchant may be performed. As the etchant, a chemical based on at least one of sulfuric acid, hydrochloric acid, and nitric acid may be used.

Here, as described above with reference to FIG. 5, since the first width W1 of the first opening 12 of the etching resist pattern 10 is adjusted so that only a portion of the metal layer 114 exposed by the first width W1 is removed and the second width W2 of the second opening 14 of the etching resist pattern 10 is adjusted so that the metal layer 114 exposed by the second width W2 is completely removed, the chemical may remove a portion of the metal layer 114 in the first region a exposed through the first opening 12 and completely remove the metal layer 114 in the second region b exposed through the second opening 14. Therefore, the first layer 115 including the non-circuit pattern having the first prominence-depression 116 formed on the surface thereof in the first region a and the circuit pattern formed in the second region b may be formed.

Referring to FIGS. 4 and 7, the second prominence-depression 117 may be formed on the first layer 115 (S140). In the forming of the second prominence-depression 117, the second prominence-depression 117 may be formed by performing a predetermined roughing treatment process on a result in which the first layer 115 is formed. As the roughing treatment process, a chemical treatment process such as a wet etching process may be used. A condition of the roughing treatment process may be adjusted so that the prominence-depressions having a size less than about 15 μm are formed on the surface of the first layer 115. Therefore, the non-circuit pattern having the first and second prominence-depressions 116 and 117 formed on the surface thereof may be formed in the first region a of the base substrate 110, and the circuit pattern having the second prominence-depression 117 formed on the surface thereof may be formed in the second region b of the base substrate 110.

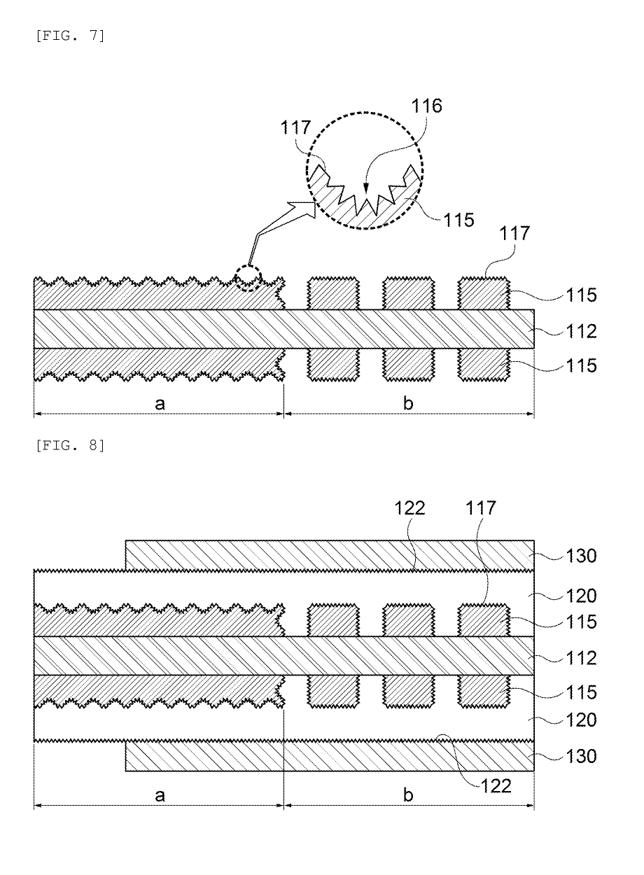

Referring to FIGS. 4 and 8, the second layer 120 having a third prominence-depression 122 may be formed on the first layer 115 (S150). For example, an insulating film may be formed on the first layer 115. The insulating film may be bonded to the first layer 115 while having a relatively wide bonding area by the first and second prominence-depressions 116 and 117 formed on the surface of the first layer 115. Particularly, the first prominence-depression 116 having a relatively large size is formed on the first layer 115 in the first region a, thereby making it possible to further increase bonding force between the first and second layers 115 and 120. In addition, the third prominence-depression 122 may be formed on the insulating layer. In the forming of the third prominence-depression 122, the third prominence-depression may be formed by performing a predetermined roughing treatment process on the insulating layer. The third prominence-depression 122 is to increase a surface area of the second layer 120 in order to improve bonding force between the second layer 120 and a film to be formed on the second layer 120.

The third layer 130 may be formed on the second layer 120 (S160). The forming of the third layer 130 may include forming a metal layer covering the second layer 120 and patterning the metal layer to form a circuit pattern or a non-circuit pattern. Here, the second and third layers 120 and 130 may be bonded to each other while having a relatively wide bonding area by the third prominence-depression 122 formed on the surface of the second layer 120.

As described above, with the method for manufacturing a circuit board according to the exemplary embodiment of the present invention, the prominence-depressions 116 and 117 having different sizes are formed on the surface of the metal layer and the insulating layer sequentially formed on the core layer 112, thereby making it possible to improve bonding force between the metal layer and the insulating layer that are vertically stacked. Therefore, with the method for manufacturing a circuit board according to the exemplary embodiment of the present invention, the circuit board having a structure in which the prominence-depressions having different sizes are formed on the surface of the metal layer and the insulating layer sequentially formed on the core layer to further improve bonding force between the metal layer and the insulating layer vertically bonded to each other may be manufactured.

In addition, with the method for manufacturing a circuit board according to the exemplary embodiment of the present invention, after the first layer 115 including the non-circuit pattern having the first and second prominence-depressions 116 and 117 formed on the surface thereof and having different sizes and the circuit pattern having only the second prominence-depression 117 formed on the surface thereof and having a size smaller than that of the first prominence-depression 116 is formed on the core layer 112, the second layer 120 may be formed on the first layer 115. Here, in the case in which the prominence-depression 116 having a relatively large size is formed on the circuit pattern, deterioration of characteristics of the circuit pattern may be prevented, and the bonding force between the first and second layers 115 and 120 may be improved. Therefore, with the method for manufacturing a circuit board according to the exemplary embodiment of the present invention, the prominence-depressions having different sizes are formed on a surface of a lower layer in order to increase the bonding force between the layers, only the prominence-depression having a relatively small size is formed in a portion used as the circuit pattern, and both of the prominence-depression having a relatively large size and the prominence-depression having a relatively small size are formed in a portion used as the non-circuit pattern, thereby making it possible to manufacture a circuit board having a structure in which deterioration of electrical characteristics of the circuit pattern is prevented and reliability of bonding between the layers is improved.

The circuit board according to the exemplary embodiment of the present invention may have a structure in which the stacked first and second layers are provided and the prominence-depressions having different sizes are provided on the surface of the first layer to improve reliability of bonding between the first and second layers.

The circuit board according to the exemplary embodiment of the present invention may have a structure in which the prominence-depressions having different sizes are formed on the surface of the first layer in order to increase the bonding force between the first and second layers sequentially stacked on the core layer, only the prominence-depression having a relatively small size is provided in the portion used as the circuit pattern, and both of the prominence-depression having a relatively large size and the prominence-depression having a relatively small size are provided in the portion used as the non-circuit pattern to prevent deterioration of electrical characteristics of the circuit pattern and improve reliability of bonding between the layers.

With the method for manufacturing a circuit board according to the exemplary embodiment of the present invention, the circuit board having a structure in which the prominence-depressions having different sizes are formed on the surface of the metal layer and the insulating layer sequentially formed on the core layer to further improve bonding force between the metal layer and the insulating layer vertically bonded to each other may be manufactured.

With the method for manufacturing a circuit board according to the exemplary embodiment of the present invention, the prominence-depressions having different sizes are formed on a surface of a lower layer in order to increase the bonding force between the layers, only the prominence-depression having a relatively small size is formed in a portion used as the circuit pattern, and both of the prominence-depression having a relatively large size and the prominence-depression having a relatively small size are formed in a portion used as the non-circuit pattern, thereby making it possible to manufacture a circuit board having a structure in which deterioration of electrical characteristics of the circuit pattern is prevented and reliability of bonding between the layers is improved.

The present invention has been described in connection with what is presently considered to be practical exemplary embodiments. Although the exemplary embodiments of the present invention have been described, the present invention may be also used in various other combinations, modifications and environments. In other words, the present invention may be changed or modified within the range of concept of the invention disclosed in the specification, the range equivalent to the disclosure and/or the range of the technology or knowledge in the field to which the present invention pertains. The exemplary embodiments described above have been provided to explain the best state in carrying out the present invention. Therefore, they may be carried out in other states known to the field to which the present invention pertains in using other inventions such as the present invention and also be modified in various forms required in specific application fields and usages of the invention. Therefore, it is to be understood that the invention is not limited to the disclosed embodiments. It is to be understood that other embodiments are also included within the spirit and scope of the appended claims.

What is claimed is:

1. A circuit board comprising:
a core layer;
a first layer covering the core layer; and
a second layer covering the first layer,
wherein prominence-depressions having different sizes are formed on a surface of the first layer in each region of the core layer.

2. The circuit board according to claim 1, wherein the prominence-depressions include:
a first prominence-depression having a size equal to or larger than 15 μm, and
a second prominence-depression having a size less than 15 μm.

3. The circuit board according to claim 1, wherein the first layer includes a circuit pattern and a non-circuit pattern,
prominence-depressions having different sizes are formed on a surface of the non-circuit pattern, and
a prominence-depression having a relatively small size among the prominence-depressions is formed on a surface of the circuit pattern.

4. The circuit board according to claim 1, wherein the first layer includes a circuit pattern and a non-circuit pattern,
a first prominence-depression having a size equal to or larger than 15 μm and a second prominence-depression having a size less than 15 μm are formed on a surface of the non-circuit pattern, and
the second prominence-depression is formed on a surface of the circuit pattern.

5. A method for manufacturing a circuit board, comprising:
preparing a base substrate having a core layer and a metal layer covering the core layer;
forming a first layer having a circuit pattern and a non-circuit pattern by performing an etching process at different etching rates on the metal layer for each region;
performing a roughing treatment process on the circuit pattern and the non-circuit pattern; and
forming a second layer on the first layer.

6. The method according to claim 5, wherein the forming of the first layer includes forming a first prominence-depression on a surface of the non-circuit pattern, the first prominence-depression having a relatively large size, and
the performing of the roughing treatment process includes forming a second prominence-depression on the circuit pattern and the non-circuit pattern, the second prominence-depression having a size smaller than that of the first prominence-depression.

7. The method according to claim 5, wherein the forming of the first layer includes forming a first prominence-depression on a surface of the non-circuit pattern, the first prominence-depression having a size equal to or larger than 15 μm, and
the performing of the roughing treatment process includes forming a second prominence-depression on the circuit pattern and the non-circuit pattern, the second prominence-depression having a size less than 15 μm.
